(19) United States
(12) Patent Application Publication
(10) Pub. No.: US 2016/0364291 A1
(43) Pub. Date: Dec. 15, 2016

(54) MEMORY SYSTEM AND METHOD OF OPERATING AND TESTING THE MEMORY SYSTEM

(71) Applicant: SK hynix Inc., Icheon-si (KR)

(72) Inventor: Hyuk Choong KANG, Seongnam-si (KR)

(21) Appl. No.: 14/938,088

(22) Filed: Nov. 11, 2015

(30) Foreign Application Priority Data
Jun. 12, 2015 (KR) 10-2015-0083634

(51) Int. Cl. G06F 11/10; G11C 29/52

(52) U.S. Cl. CPC G06F 11/1068; G11C 29/52

(57) ABSTRACT

A memory system may include a plurality of chips configured to have an operation speed of a predetermined target speed or less. The memory system may include an error correction code (ECC) circuit configured to correct an error of each chip having an operation speed of higher than the target speed from among the plurality of chips.

### CROSS-REFERENCE TO RELATED APPLICATION

This application claims priority based upon Korean patent application No. 10-2015-0083634, filed on Jun. 12, 2015, the disclosure of which is hereby incorporated in its entirety by reference herein.

### BACKGROUND

1. Technical Field

Embodiments of the present disclosure may generally relate to a memory system, and a method of operating and testing a memory system.

2. Related Art

In order to release high-speed products after completion of device development, all tests from a low-speed test to a high-speed test are needed. Testing in this manner results in the occurrence of high test costs.

In the low-speed test, the most defective parts, for example, a row failure (also called a row failure), a column failure (also called a column failure), and a bit failure (also called a bit fail), can be addressed. However, as operational speeds increase, the number of bit failures increase, such test costs rapidly increase only to solve a small number of defective cells. Specifically, if the memory becomes superannuated or deteriorated, an unexpected product failure may occur prior to expiration of a product warranty period.

In order to satisfy the product specifications according to development and widespread use of higher-speed devices, various associated tests are needed, such that the associated costs for such tests are rapidly increasing.

### SUMMARY

In an embodiment, there may be provided a memory system. The memory system may include a plurality of chips configured to have an operation speed of a predetermined target speed or less. The memory system may include an error correction code (ECC) circuit configured to correct an error of each chip having an operation speed of greater than the target speed from among the plurality of chips.

In an embodiment, there may be provided a memory system. The memory system may include a low-speed chip group including a plurality of chips configured to operate at a lower speed as compared to predetermined standard characteristics. The memory system may include a high-speed chip group including a plurality of chips configured to operate at a higher speed as compared to the standard characteristics. The memory system may include a first error correction code (ECC) circuit configured to correct an error of the low-speed chip group. The memory system may include a second error correction code (ECC) circuit configured to correct an error of the high-speed chip group.

In an embodiment, there may be provided a memory system. The memory system may include a first chip group including a plurality of chips, each of which has a data transfer rate of a first speed or less, such that a speed binning test is performed on the plurality of chips. The memory system may include a second chip group including a plurality of chips, each of which has a data transfer rate that is higher than a first speed and equal to or less than a second speed. The memory system may include a third chip group including a plurality of chips, each of which has a data transfer rate higher than the second speed. The memory system may include a first error correction code (ECC) circuit configured to correct an error of the second chip group. The memory system may include a second error correction code (ECC) circuit configured to correct an error of the third chip group.

In an embodiment, there may be provided a method of testing and operating a memory system. The method may include performing a speed binning test on a plurality of chips having an operation speed of a predetermined target speed or less. The method may include correcting an error of each chip with an error correction code (ECC) circuit having an operation speed greater than the target speed from among the plurality of chips.

### BRIEF DESCRIPTION OF THE DRAWINGS

FIG. 1 is a schematic diagram illustrating a representation of an example of a memory system according to an embodiment of the present disclosure.

FIG. 2 is a schematic diagram illustrating a representation of an example of a memory system according to an embodiment of the present disclosure.

FIG. 3 is a flowchart illustrating a representation of an example of a method relating to testing and operating the memory systems related to an embodiment of FIGS. 1 and/or 2.

FIG. 4 illustrates a block diagram of an example of a representation of a system employing a memory system and/or method of operating and/or testing the memory system in accordance with the various embodiments discussed above with relation to FIGS. 1-3.

### DETAILED DESCRIPTION

Reference will now be made to embodiments of the present disclosure, examples of which are illustrated in the accompanying drawings. Wherever possible, the same reference numbers are used throughout the drawings to refer to the same or like portions. In the following description of the present disclosure, a detailed description of related known configurations or functions incorporated herein may be omitted for clarity of the subject matter of the present disclosure.

Generally, there may be a need to develop a memory system configured to reduce product development costs including test costs as well as a memory system that can operate at a high speeds.

Various embodiments of the present disclosure may be directed to providing a memory system that substantially obviates one or more problems due to limitations and disadvantages of the related art.

The embodiments of the present disclosure may relate to a memory system in which a low-speed chip and a high-speed chip are implemented as a single DIMM (Dual In-line Memory Module), and an error correction code (ECC) having different performances may be applied to individual chips, which may result in the reduction of test costs.

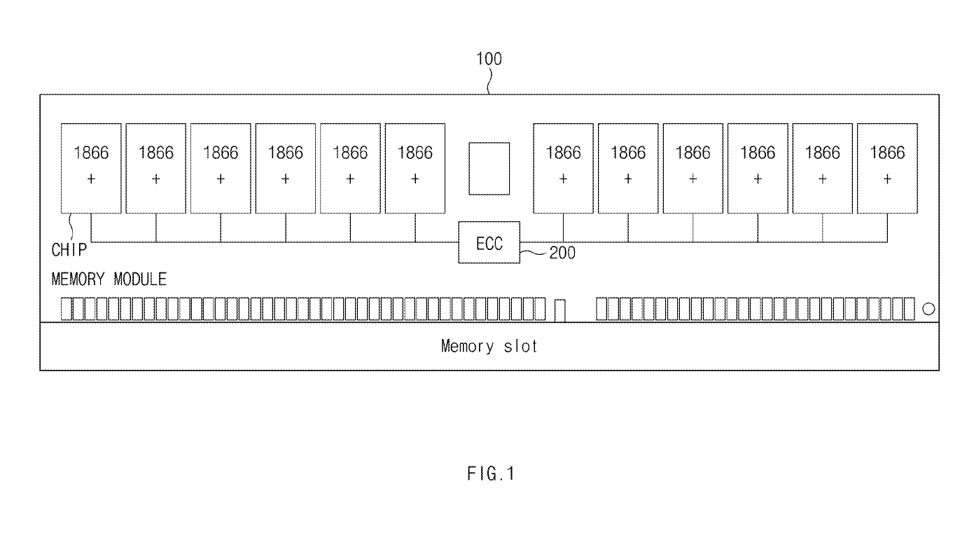

FIG. 1 is a schematic diagram illustrating a representation of an example of a memory system according to an embodiment of the present disclosure.

Referring to FIG. 1, a single memory module 100 may include a plurality of chips. Errors by the chips may be corrected by an Error Correction Code (ECC) circuit 200. FIG. 1 also illustrates a memory slot. A semiconductor fabrication process may actually be based on statistics. That is, when the same chips, the number of which is statistically meaningful, are manufactured, some of the chips (referred to as first chips) may operate at a target speed or less, some of the chips (referred to as second chips) may operate at the target speed, and some of the chips (referred to as third chips) may operate at a speed greater than the target speed.

The first chips are categorized as chips having low speed characteristics (referred to as low-speed chips), the second chips are categorized as chips having standard characteristics (referred to as standard chips), and the third chips are categorized as chips having high speed characteristics (referred to as high-speed chips). Generally, the high-speed chips are advantageous over other chips in terms of costs, and low-speed chips are relatively cheaper than the standard chips.

However, power consumption of low-speed chips is less than the power consumption of standard chips, and power consumption of standard chips is less than the power consumption of the high-speed chips. Therefore, before DRAM core chips are attached to interface chips, the DRAM core chips may be classified according to maximum operation speeds of the chips. The classification of the DRAM core chips may be referred to as “speed binning”.

For example, interface chips (applicable to, for example, mobile phones) designed, for example, for low-power products may be attached to low-speed core components. Interface chips (applicable to, for example, game consoles) designed for high-performance/high-speed products may be attached to high-speed core components. Interface chips (applicable to, for example, servers) designed for lower-power and higher-performance products can be attached to standard core components. Therefore, all kinds of core chips may have unique characteristics and unique uses such that the core chips can be used in various ways.

Generally, speed binning of memory chips may be carried out after completion of chip packaging. However, speeds of memory chips may also be classified according to wafer levels as necessary. In order to perform speed classification or speed binning, automatic testing devices or the like can be used.

During speed binning of the chips, a time needed for the basic operations (for example, read, write (record), activation, and refresh operations, etc.) is measured. In order to meet such requirements, chips (e.g., DRAM core chips) according to the embodiments may be operated independently from each other. In addition, the chips according to the embodiments may test all times and all functions needed to access internal arrays configured to store data therein.

A plurality of chips contained in the memory module 100 according to the embodiments of the present disclosure may perform the binning test at a speed of less than a predetermined standard speed. That is, the binning test may be performed only at a minimum speed, and the ECC circuit 200 may be simultaneously applied at the remaining speeds, resulting in reduction of test costs. In this example, a data transfer rate of less than a predetermined standard speed may be denoted by 1866 Mbps.

In this example, the binning-processed chips may be unable to satisfy a condition of the predetermined standard speed or higher. However, when low-speed chips are tested, test costs can be reduced.

Although low-speed chips have a low data transfer rate, there is a low probability that a relatively smaller number of bit failures may occur in the low-speed chips as compared to the standard chips. Therefore, assuming, for example, that at least one bit failure occurs in respective chips after completion of a minimum number of low-speed tests required for memory specifications, error correction is performed through the ECC circuit 200.

Therefore, the memory module 100 can be implemented as illustrated in FIG. 1, which has high-speed characteristics and may be implemented with a relatively low test cost using chips having low-speed characteristics.

For convenience of description and better understanding of the present disclosure, each chip of the memory module 100 according to the embodiments of the present disclosure may include a Dynamic Random Access Memory (DRAM). However, the scope or spirit of the present disclosure is not limited thereto, and the chip of the memory module 100 may also be applied to other kinds of memories, for example, RAM (Random Access Memory), SRAM (Static Random Access Memory), ROM (Read Only Memory), PROM (Programmable Read Only Memory), OTP (One-Time Programmable) memory, etc.

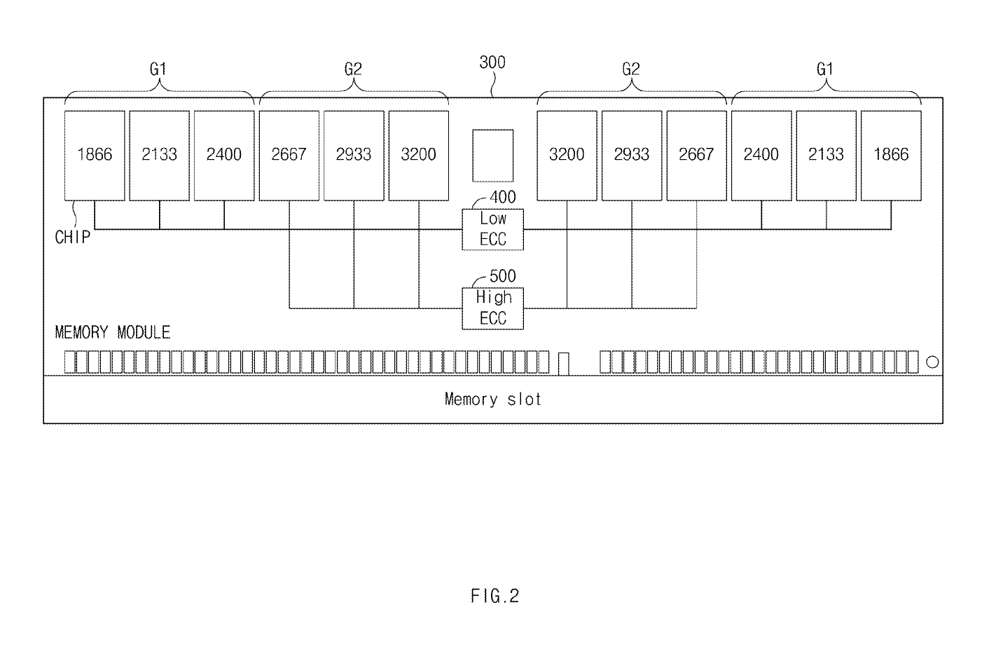

FIG. 2 is a schematic diagram illustrating a representation of an example of a memory system according to an embodiment of the present disclosure.

Referring to FIG. 2, one memory module 300 may include a plurality of chips. In this example, the chips are classified into a low-speed chip group G1 and a high-speed chip group G2. The chips of the low-speed chip group G1 may operate at a lower speed than standard chips, such that the chips of the group G1 are classified as low-quality products. The chips of the high-speed chip group G2 may operate at a higher speed than the standard chips, such that the chips of the group G2 are classified as high-quality products.

For example, the low-speed chip group G1 may include chips respectively having data transfer rates of 1866, 2133, and 2400 Mbps. The high-speed chip group G2 may include chips respectively having data transfer rates of 2667, 2933, and 3200 Mbps. However, reference numerals illustrated in FIG. 2 are merely exemplary, a data transfer rate of the low-speed chip group G1 and a data transfer rate of the high-speed chip group G2 may be changed according to design situations.

The low-speed chip group G1 may be coupled to a low ECC circuit 400, such that error correction is performed. The high-speed chip group G2 may be coupled to a high ECC circuit 500, such that error correction is performed.

In this example, whereas the low ECC circuit 400 is small in size and has low ECC efficiency, the low ECC circuit 400 has relatively low-priced costs. The low ECC circuit 400 is configured to perform 1-bit correction.

In contrast, whereas the high ECC circuit 500 is small in size, the high ECC circuit has relatively high ECC efficiency. The high ECC circuit 500 may correct multiple bits.

That is, the low-speed chip group G1 performs error correction using the low ECC circuit 400, resulting in reduction of production costs. The high-speed chip group G2 performs error correction using the high ECC circuit 500, resulting in increased ECC efficiency.

That is, in order to reduce test costs of the memory module 300, the low ECC circuit 400 and the high ECC circuit may be used. However, assuming that the same On Die ECC circuits are applied to one memory module 300, die overhead unavoidably increases, resulting in reduction of profitability.

Therefore, according to the embodiments of the present disclosure, ECC circuits (400, 500) having different qualities may be applied to the low-speed chip group G1 and the high-speed chip group G2, such that test costs can be reduced and ECC efficiency can be improved.

After completion of speed binning, high-quality products may be combined with each other, resulting in implementation of a single module. However, low-quality products are classified due to the occurrence of some bit failures.

As a result, according to the embodiments of the present disclosure, the low-speed chip group G1 and the high-speed chip group G2 are combined with each other after completion of the speed binning operation, such that one memory module 300 having high-speed characteristics can be implemented.

That is, the low-speed chip group G1 belonging to the low-speed binning device is contained in one memory module 300. In addition, errors of the low-speed chip group G1 are corrected, such that the resultant low-speed chip group G1 is contained in the same high-speed memory module 300 as in the high-speed chip group G2.

Generally, the speed binning test for all chips is performed so that a bit failure aspect can be checked. In addition, chips belonging to the chip group G2 having the smallest number of bit failures at a high speed during the speed binning test may be classified as high-speed products.

For example, the binning test is applied to the low-speed chip group G1 having a data transfer rate of 2400 Mbps or less, and errors of the high-speed chip group G2 having a data transfer rate of 2667 Mbps or higher can be corrected through the ECC circuit 500. Therefore, according to the embodiments of the present disclosure, the speed binning test costs can be reduced and high-speed DIMM can be efficiently used.

As described above, chips, each of which has a small number of bit failures, contained in the high-density memory module 300 can be immediately fabricated in the form of a module, and the number of high-speed binning tests can be reduced, resulting in reduction of development costs.

Although chips are classified into the low-speed chip group G1 and the high-speed chip group G2 and the binning test is performed on the low-speed chip group G1 and the high-speed chip group G2, it should be noted that a data transfer rate for classifying the chip groups is not limited.

For example, the binning test may be performed on the chip having a data transfer rate of 1886 Mbps, the low ECC circuit 400 may be applied to the chip having a data transfer rate of 2133˜2667 Mbps, and the high ECC circuit 500 may be applied to the chip having a data transfer rate of 2933 or 3200 Mbps, such that error correction may be performed.

In addition, the binning test may be performed on all chips having all speed ranges, and the same ECC may also be applied to devices in which bit failures occur.

In the memory module 100 or 300 according to the embodiments, the same or different types of memories are combined such that the combined result is implemented as one module. The memory module 100 or 300 according to the embodiments may be implemented as a Non Volatile Dual In-line Memory Module (NIDIMM). The NVDIMM may indicate a module formed by combination of a non-volatile memory and a volatile memory.

As described above, although the embodiments can be exemplarily applied to NVDIMM for convenience of description and better understanding of the present disclosure, the scope or spirit of the present disclosure is not limited thereto, and can be applied to all kinds of memory systems configured to store volatile cell information using non-volatile memories such as hybrid DIMM and general DIMM.

In addition, the memory module 100 or 300 according to the embodiments may also be comprised of Unbuffered Dual In-line Memory Module (UDIMM), Registered Dual In-line Memory Module (RDIMM), Fully Buffered Dual In-line Memory Module (FBDIMM), Load Reduced Dual In-line Memory Module (LRDIMM), or any other memory modules.

As is apparent from the above description, the memory system according to the embodiments of the present disclosure can greatly reduce test costs in DIMM.

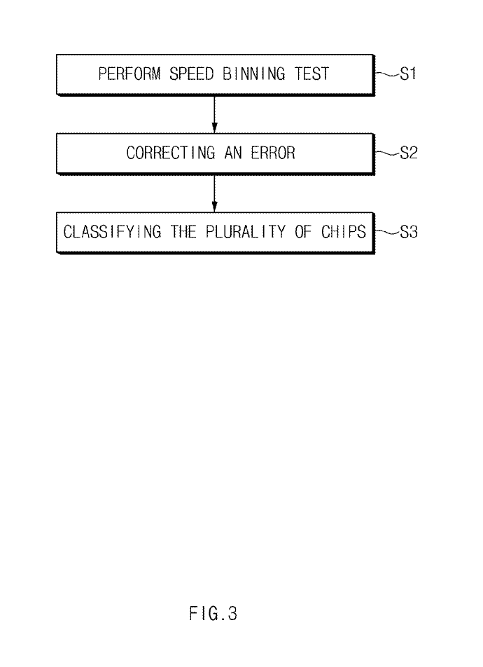

FIG. 3 is a flowchart illustrating a representation of an example of a method relating to testing and operating the memory systems related to an embodiment of FIGS. 1 and/or 2.

Referring to FIG. 3, in step 1 (S1) a speed binning test is performed on a plurality of chips having an operation speed of a predetermined target speed or less. In an embodiment, time need for a basic operation of the plurality of chips may be measured when the speed binning test in step 1 (S1) is being performed. In step 2 (S2), correcting an error of each chip with an error correction code (ECC) circuit having an operation speed greater than the target speed from among the plurality of chips is performed. In step 3 (S3), the plurality of chips are classified as low-speed chips if an operation speed of the chip is at the predetermined target speed or less as determined by the speed binning test. In an embodiment, the plurality of chips may have the same low-speed operation characteristics. In an embodiment, errors of the plurality of chips may be corrected by the error correction code (ECC) circuit when a bit failure occurs in the plurality of chips after a minimum number of low-speed tests needed for a memory specification is performed. In an embodiment, each of the plurality of chips may include a Dynamic Random Access Memory (DRAM). In an embodiment, the plurality of chips and the ECC circuit may be contained in Dual In-line Memory Module (DIMM).

As is apparent from the above description, the memory system according to the embodiments of the present disclosure can greatly reduce test costs in DIMM.

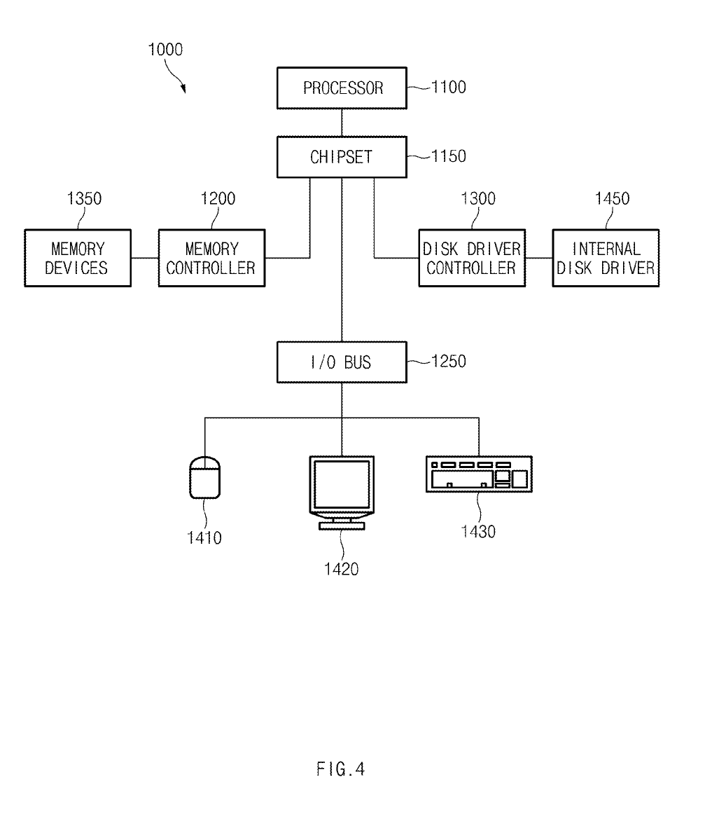

The memory system and/or method of operating and/or testing the memory system discussed above (see FIGS. 1-3) are particular useful in the design of memory devices, processors, and computer systems. For example, referring to FIG. 4, a block diagram of a system employing a memory system and/or method of operating and/or testing the memory system in accordance with the various embodiments are illustrated and generally designated by a reference numeral 1000. The system 1000 may include one or more processors (i.e., Processor) or, for example but not limited to, central processing units (“CPUs”) 1100. The processor (i.e., CPU) 1100 may be used individually or in combination with other processors (i.e., CPUs). While the processor (i.e., CPU) 1100 will be referred to primarily in the singular, it will be understood by those skilled in the art that a system 1000 with any number of physical or logical processors (i.e., CPUs) may be implemented.

A chipset 1150 may be operably coupled to the processor (i.e., CPU) 1100. The chipset 1150 is a communication pathway for signals between the processor (i.e., CPU) 1100 and other components of the system 1000. Other components of the system 1000 may include a memory controller 1200, an input/output (“I/O”) bus 1250, and a disk driver controller 1300. Depending on the configuration of the system 1000, any one of a number of different signals may be transmitted through the chipset 1150, and those skilled in the art will appreciate that the routing of the signals throughout the system 1000 can be readily adjusted without changing the underlying nature of the system 1000.

As stated above, the memory controller 1200 may be operably coupled to the chipset 1150. The memory controller 1200 may include at least one memory system and/or employ a method of operating and/or testing the memory system as discussed above with reference to FIGS. 1-3. Thus, the memory controller 1200 can receive a request provided from the processor (i.e., CPU) 1100, through the chipset 1150. In alternate embodiments, the memory controller 1200 may be integrated into the chipset 1150. The memory controller 1200 may be operably coupled to one or more memory devices 1350. In an embodiment, the memory devices 1350 may include the at least one memory system and/or employ a method of operating and/or testing the memory system as discussed above with relation to FIGS. 1-3, the memory devices 1350 may include a plurality of word lines and a plurality of bit lines for defining a plurality of memory cells. The memory devices 1350 may be any one of a number of industry standard memory types, including but not limited to, single inline memory modules (“SIMMs”) and dual inline memory modules (“DIMMs”). Further, the memory devices 1350 may facilitate the safe removal of the external data storage devices by storing both instructions and data.

The chipset 1150 may also be coupled to the I/O bus 1250. The I/O bus 1250 may serve as a communication pathway for signals from the chipset 1150 to I/O devices 1410, 1420, and 1430. The I/O devices 1410, 1420, and 1430 may include, for example but are not limited to, a mouse 1410, a video display 1420, or a keyboard 1430. The I/O bus 1250 may employ any one of a number of communications protocols to communicate with the I/O devices 1410, 1420, and 1430. In an embodiment, the I/O bus 1250 may be integrated into the chipset 1150.

The disk driver controller 1300 may be operably coupled to the chipset 1150. The disk driver controller 1300 may serve as the communication pathway between the chipset 1150 and one internal disk driver 1450 or more than one internal disk driver 1450. The internal disk driver 1450 may facilitate disconnection of the external data storage devices by storing both instructions and data. The disk driver controller 1300 and the internal disk driver 1450 may communicate with each other or with the chipset 1150 using virtually any type of communication protocol, including, for example but not limited to, all of those mentioned above with regard to the I/O bus 1250.

It is important to note that the system 1000 described above in relation to FIG. 4 is merely one example of a system 1000 employing a memory system and/or a method of operating and/or testing the memory system as discussed above with relation to FIGS. 1-3. In alternate embodiments, such as, for example but not limited to, cellular phones or digital cameras, the components may differ from the embodiments illustrated in FIG. 4.

Those skilled in the art will appreciate that the embodiments may be carried out in other specific ways than those set forth herein without departing from the spirit and essential characteristics of the description. The above embodiments are therefore to be construed in all aspects as illustrative and not restrictive. The scope of the disclosure should be determined by the appended claims and their legal equivalents, not by the above description. Further, all changes coming within the meaning and equivalency range of the appended claims are intended to be embraced therein. In addition, it is obvious to those skilled in the art that claims that are not explicitly cited in each other in the appended claims may be presented in combination as an embodiment of the invention or included as a new claim by a subsequent amendment after the application is filed.

Although a number of illustrative embodiments consistent with the invention have been described, it should be understood that numerous other modifications and embodiments can be devised by those skilled in the art that will fall within the spirit and scope of the principles of this disclosure. Particularly, numerous variations and modifications are possible in the component parts and/or arrangements which are within the scope of the disclosure, the drawings and the accompanying claims. In addition to variations and modifications in the component parts and/or arrangements, alternative uses will also be apparent to those skilled in the art.

What is claimed is:

1. A memory system comprising:
a plurality of chips configured to have an operation speed of a predetermined target speed or less; and
an error correction code (ECC) circuit configured to correct an error of each chip having an operation speed of greater than the target speed from among the plurality of chips.

2. The memory system according to claim 1, wherein the plurality of chips are classified into low-speed chips, each of which has the operation speed of the target speed or less, by the speed binning test.

3. The memory system according to claim 1, wherein the plurality of chips have the same low-speed operation characteristics.

4. The memory system according to claim 1, wherein errors of the plurality of chips are corrected by the error correction code (ECC) circuit when a bit failure occurs in the plurality of chips after a minimum number of low-speed tests needed for a memory specification is performed.

5. The memory system according to claim 1, wherein each of the plurality of chips includes a Dynamic Random Access Memory (DRAM).

6. The memory system according to claim 1, wherein:
when the speed binning test is performed, a time needed for a basic operation of the plurality of chips is measured.

7. The memory system according to claim 1, wherein the plurality of chips and the ECC circuit are contained in Dual In-line Memory Module (DIMM).

8. A memory system comprising:
a low-speed chip group including a plurality of chips configured to operate at a lower speed as compared to predetermined standard characteristics;
a high-speed chip group including a plurality of chips configured to operate at a higher speed as compared to the standard characteristics;
a first error correction code (ECC) circuit configured to correct an error of the low-speed chip group; and
a second error correction code (ECC) circuit configured to correct an error of the high-speed chip group.

9. The memory system according to claim 8, wherein the low-speed chip group is classified into low-quality products.

10. The memory system according to claim 8, wherein the high-speed chip group is classified into high-quality products.

11. The memory system according to claim 8, wherein the low-speed chip group includes a plurality of chips configured to operate at a lower speed as compared to the standard characteristics and to have different data transfer rates.

12. The memory system according to claim 8, wherein the high-speed chip group includes a plurality of chips configured to operate at a higher speed as compared to the standard characteristics and to have different data transfer rates.

13. The memory system according to claim 8, wherein the first error correction code (ECC) circuit and the second error correction code (ECC) circuit have different error correction qualities.

14. The memory system according to claim 8, wherein the first error correction code (ECC) circuit is a circuit capable of performing 1-bit correction.

15. The memory system according to claim 8, wherein the second error correction code (ECC) circuit is a circuit capable of performing multi-bit correction.

16. The memory system according to claim 8, wherein:
a speed binning test is used to determine the low-speed chip group.

17. The memory system according to claim 8, wherein the memory system is applied to a Dual In-line Memory module (DIMM).

18. The memory system according to claim 8, wherein each of the low-speed chip group and the high-speed chip group includes a Dynamic Random Access Memory (DRAM).

19. A memory system comprising:
a first chip group including a plurality of chips, each of which has a data transfer rate of a first speed or less, such that a speed binning test is performed on the plurality of chips;
a second chip group including a plurality of chips, each of which has a data transfer rate that is higher than a first speed and equal to or less than a second speed;
a third chip group including a plurality of chips, each of which has a data transfer rate higher than the second speed;
a first error correction code (ECC) circuit configured to correct an error of the second chip group; and
a second error correction code (ECC) circuit configured to correct an error of the third chip group.

20. The memory system according to claim 19, wherein the memory system is applied to Dual In-line Memory Module (DIMM).

21. A method of testing and operating a memory system, the method comprising:
performing a speed binning test on a plurality of chips having an operation speed of a predetermined target speed or less; and
correcting an error of each chip with an error correction code (ECC) circuit having an operation speed greater than the target speed from among the plurality of chips.

22. The method according to claim 21, further comprising:
classifying the plurality of chips as low-speed chips if an operation speed of the chip is at the predetermined target speed or less as determined by the speed binning test.

23. The method according to claim 21, wherein the plurality of chips have the same low-speed operation characteristics.

24. The method according to claim 21, wherein errors of the plurality of chips are corrected by the error correction code (ECC) circuit when a bit failure occurs in the plurality of chips after a minimum number of low-speed tests needed for a memory specification is performed.

25. The method according to claim 21, wherein each of the plurality of chips includes a Dynamic Random Access Memory (DRAM).

26. The method according to claim 21, further comprising:
measuring a time needed for a basic operation of the plurality of chips when the speed binning test is performed.

27. The method according to claim 21, wherein the plurality of chips and the ECC circuit are contained in Dual In-line Memory Module (DIMM).
